(19) United States
(12) Patent Application Publication
(10) Pub. No.: US 2013/0084678 A1
(43) Pub. Date: Apr. 4, 2013

(54) Method Of Manufacturing Package-On-Package (Pop)

(71) Applicant: Byeong Ho Jeong, Gyeonggi-do (KR)

(72) Inventor: Byeong Ho Jeong, Gyeonggi-do (KR)

(21) Appl. No.: 13/627,611

(22) Filed: Sep. 26, 2012

(30) Foreign Application Priority Data
Sep. 30, 2011 (KR) 10-2011-0100355

(51) Int. Cl. H01L 21/50

(52) U.S. Cl. 438/108; 438/109; 257/E21.499

(57) ABSTRACT

A method of manufacturing package-on-packages (POPs) includes: forming a plurality of internal connection members that are separated from each other on a first circuit substrate; forming a first package by attaching a plurality of first chips between the internal connection members on the first circuit substrate; forming a second package by attaching a plurality of second chips that are separated from each other on a second circuit substrate; electrically connecting the first circuit substrate and the second circuit substrate by stacking the internal connection members onto the second circuit substrate; forming an encapsulant to encapsulate the first package and the second package; and forming the POPs in which the first chips and the second chips are respectively formed by cutting the first circuit substrate, the second circuit substrate, and the encapsulant.

### FIELD OF THE INVENTION

The present invention relates to a method of manufacturing a semiconductor package, and more particularly, to a method of manufacturing package-on-packages (POPs) in which a second package is stacked on a first package.

### BACKGROUND OF THE INVENTION

Semiconductor industries desire to manufacture semiconductor products having high reliability with a small size, multifunction, and a high capacity. One of the key technologies that enables to achieve the multiple targets is the semiconductor package technique. As a method of achieving the multiple targets described above, of the key technologies, package-on-packages (POPs) in which a second package is stacked on a first package has been proposed.

### SUMMARY OF THE INVENTION

The present invention provides a method of manufacturing package-on-packages (POPs) that enables to manufacture semiconductor products having a small size, multifunction, and a high capacity with a low cost and a simple process.

According to an aspect of the present invention, there is provided a method of manufacturing package-on-packages (POPs), the method including: forming a plurality of internal connection members that are separated from each other in a direction parallel to a first circuit substrate on the first circuit substrate; forming a first package by attaching a plurality of first chips between the internal connection members on the first circuit substrate; forming a second package by attaching a plurality of second chips that are separated from each other in a direction parallel to a second circuit substrate on the second circuit substrate; electrically connecting the first circuit substrate and the second circuit substrate by stacking and attaching the second circuit substrate onto internal connection members formed on the first circuit substrate on a circuit substrate level; forming an encapsulant to encapsulate the first package and the second package; and forming POPs in which the first chips and the second chips are respectively formed on the first circuit substrate and the second circuit substrate by cutting the first circuit substrate, the second circuit substrate, and the encapsulant.

The method may further include forming external connection members on a lower surface of the first circuit substrate. The first chips and the second chips may be electrically connected to the first circuit substrate and the second circuit substrate respectively through first chip connection members and second chip connection members.

The first and second chip connection members may be formed as a plurality of chip connection terminals. The method may further include forming an underfill layer between the chip connection terminals of the first circuit substrate or the second circuit substrate. The first and second chips may be respectively attached to the first and second circuit substrate in a flip chip method.

The chip connection terminals and the internal connection members may be formed as solder balls. The second chips may be of the same kind as or a different kind than the first chips. The internal connection members may have a height greater than that of the first chips on the first circuit substrate.

Also, there is provided a method of manufacturing package-on-packages (POPs), the method including: forming a plurality of internal connection members that are separated from each other on a first circuit substrate; forming a first package by attaching a plurality of first chips between the internal connection members on the first circuit substrate; forming a second package by attaching a plurality of second chips that are separated from each other on a second circuit substrate; electrically connecting the first circuit substrate and the second circuit substrate by stacking the second circuit substrate onto the internal connection members; forming an encapsulant to encapsulate the first package and the second package; and forming the POPs in which the first chips and the second chips are respectively formed on the first circuit substrate and the second circuit substrate by cutting a portion of the first circuit substrate, the second circuit substrate, and the encapsulant.

### BRIEF DESCRIPTION OF THE DRAWINGS

The above and other features and advantages of the present invention will become more apparent by describing in detail exemplary embodiments thereof with reference to the attached drawings in which:

FIGS. 1 and 2 are cross-sectional views showing a method of manufacturing a first embodiment of a first package in a package-on-packages (POP) of the present invention;

FIG. 3 is a cross-sectional view showing a method of manufacturing a second embodiment of a first package in the POP of the present invention;

FIG. 4 is a cross-sectional view showing a method of manufacturing a first embodiment of a second package in a POP of the present invention;

FIG. 5 is a cross-sectional view showing a method of manufacturing a second embodiment of a second package in the POP of the present invention;

FIGS. 6 through 9 are cross-sectional views showing a method of manufacturing a POP according to a first embodiment of the present invention;

FIGS. 10 and 11 are cross-sectional views showing a method of manufacturing a POP according to a second embodiment of the present invention; and

FIG. 12 is a flow chart for explaining a method of manufacturing a POP according to the first and second embodiments of the present invention.

### DETAILED DESCRIPTION OF THE INVENTION

Hereafter, the present invention will be described more fully with reference to the accompanying drawings. These embodiments are provided so that this disclosure will be thorough and complete, and will fully convey the scope of the invention to one of ordinary skill in the art. This invention may, however, be embodied in many different forms and may be made various changes. While exemplary embodiments are capable of various modifications and alternative forms, embodiments thereof are shown by way of example in the drawings and will herein be described in detail.

It should be understood, however, that there is no intent to limit exemplary embodiments to the particular forms disclosed, but on the contrary, example embodiments are to cover all modifications, equivalents, and alternatives falling within the scope of the invention. Like numbers refer to like elements throughout the description of the figures. In the drawings, dimensions of structures may be exaggerated or reduced than actual sizes for clarity.

The terminology used herein is for the purpose of describing particular embodiments only and is not intended to be limiting of the invention. The singular forms include the plural forms unless the context clearly indicates otherwise. It will further understood that the terms “comprise” and/or “comprising” when used in this specification, specify the presence of stated features, integers, operations, operations, elements, and/or components, but do not preclude the presence or addition of one or more other features, integers, operations, operations, elements, components, and/or groups thereof.

Spatially relative terms, such as “on’ or “above”, “below” or “lower” and the like, may be used herein for ease of description to describe the relationship of one of element or feature to another element(s) as illustrated in the figures. It will be understood that the spatially relative terms are intended to encompass different orientations of the devices in use or operation. For example, if the device in the figures is turned over, the elements described as “below” other elements or features would then be oriented “above” the other elements or features. Thus, the exemplary term “below” can encompass both an orientation of above and below. The device may be otherwise orientated (rotated 90 degrees or at other orientations) and the spatially relative descriptions used interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used in dictionaries, should be interpreted as having a meaning that is consistent with their meaning in the context of the relevant art and will not be interpreted in an idealized or overly formal senses unless expressly so defined herein.

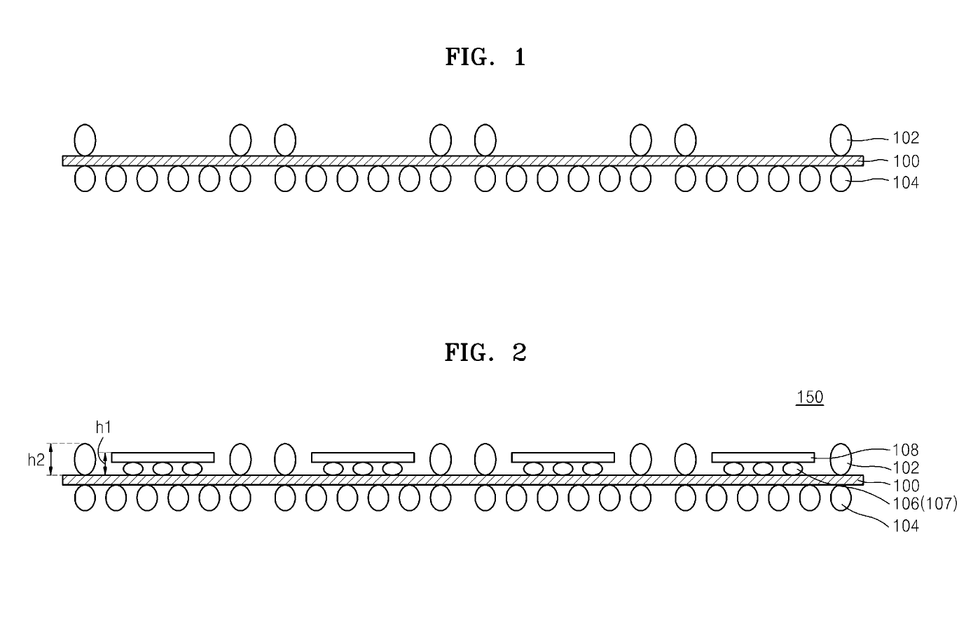

FIGS. 1 and 2 are cross-sectional views showing a method of manufacturing a first embodiment of a first package 150 in a package-on-packages (POP) of the present invention.

Specifically, a plurality of internal connection members 102 that are separated from each other in a direction parallel to a first circuit substrate 100 are formed on the first circuit substrate 100. In FIGS. 1 and 2, the internal connection members 102 may be formed separate from each other in right and left directions. Gaps having a relatively large width between the internal connection members 102 may be portions where first chips 108 are attached in a subsequent process. On the first circuit substrate 100, the internal connection members 102 may have a height greater than that of the first chips 108, which are attached in a subsequent process.

The first circuit substrate 100 may be a printed circuit board (PCB). The internal connection members 102 may be formed as solder balls or solder bumps. If necessary, a plurality of external connection members 104 may be formed on a lower surface of the first circuit substrate 100. The external connection members 104 may be formed as solder balls.

Referring to FIG. 2, the manufacture of the first package 150 is completed by attaching the first chips 108 onto the first circuit substrate 100 between the internal connection members 102. As described above, the first chips 108 are attached via the gaps having a relatively large width between the internal connection members 102. The first chips 108 may be attached to the first circuit substrate 100 in a flip chip method. The height h1 of the first chips 108 may be lower than the height 2 of the internal connection members 102.

The first chips 108 may be electrically connected to the first circuit substrate 100 through first chip connection members 106. The first chip connection members 106 may be formed as a plurality of chip connection terminals 107. The chip connection terminals 107 may be formed as solder balls. The first package 150 includes the first chips 108 that are connected through the first chip connection members 106 and the internal connection members 102 on the first circuit substrate 100. The first package 150 may be referred to as a package substrate because it is not an individual package.

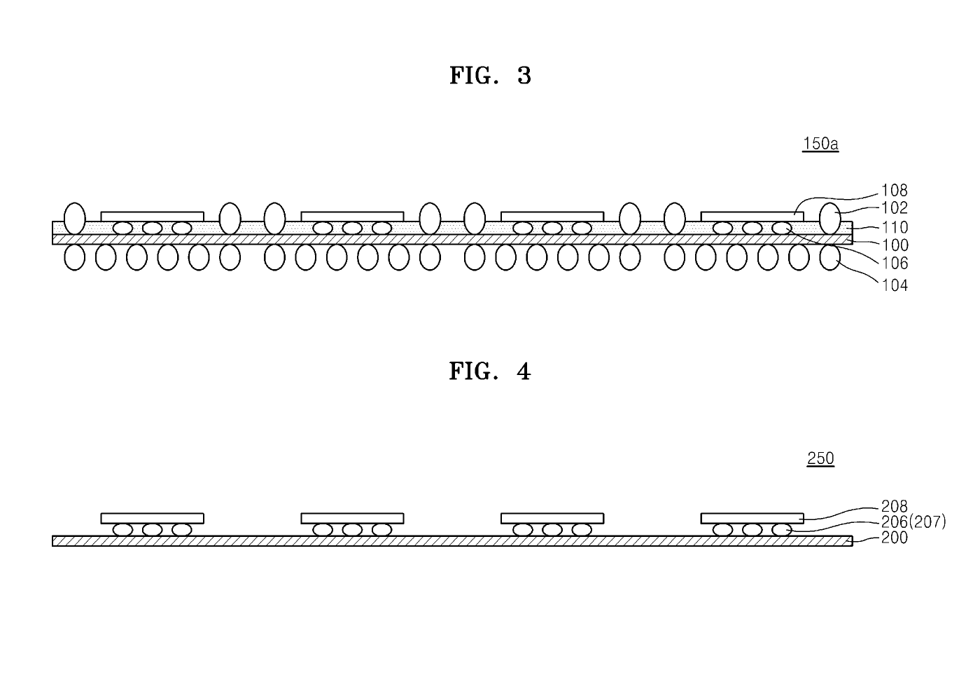

FIG. 3 is a cross-sectional view showing a method of manufacturing a second embodiment of a first package 150a in the POP of the present invention.

Specifically, the second embodiment of the first package 150a is substantially the same as the first embodiment of the first package 150 except for a first underfill layer 110 that is formed between the chip connection terminals 107 that constitute the first chip connection members 106, which are formed on the first circuit substrate 100.

The first underfill layer 110 is formed to increase insulation between the chip connection terminals 107 and to increase the attachment of the first chips 108 to the first circuit substrate 100. The first underfill layer 110 may be formed between the internal connection members 102 on the first circuit substrate 100. The first underfill layer 110 may be formed of a resin, for example, an epoxy resin.

FIG. 4 is a cross-sectional view showing a method of manufacturing a first embodiment of a second package 250 in a POP of the present invention.

Specifically, the manufacture of the second package 250 is completed by attaching a plurality of second chips 208 that are separated from each other in a direction parallel to a second circuit substrate 200 on the second circuit substrate 200. The second circuit substrate 200 may be a PCB. The second chips 208 may be attached to the second circuit substrate 200 in a flip chip method.

The second chips 208 may be electrically connected to the second circuit substrate 200 through second chip connection members 206. The second chip connection members 206 may be formed as a plurality of chip connection terminals 207. The second chips 208 may be of the same kind as or a different kind than the first chips 108.

The second chip connection members 206 may be formed as solder balls. The second package 250 includes the second chips 208 attached to the second circuit substrate 200 through the second chip connection members 206. The second package 250 may be referred to as a package substrate because it is not an individual package.

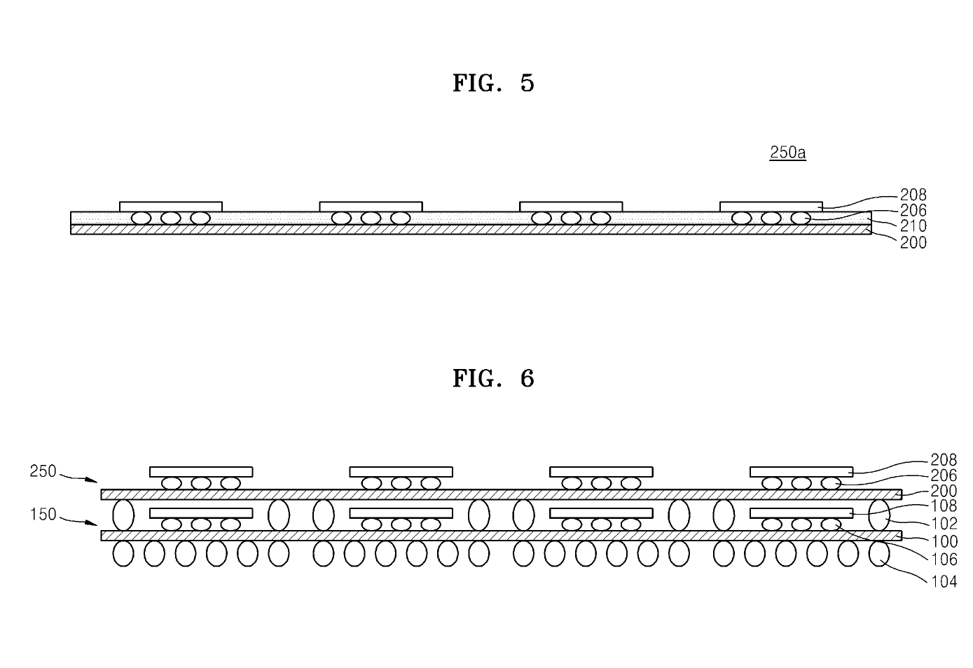

FIG. 5 is a cross-sectional view showing a method of manufacturing a second embodiment of a second package 250a in the POP of the present invention.

Specifically, the second embodiment of the second package 250a is substantially the same as the first embodiment of second package 250 except for a second underfill layer 210 that is formed between the chip connection terminals 207 that constitute the second chip connection members 206, which are formed on the second circuit substrate 200.

The second underfill layer 210 is formed to increase insulation between the chip connection terminals 207 and to increase the attachment of the first chips 208 to the second circuit substrate 200. The second underfill layer 210 may be formed of a resin, for example, an epoxy resin.

FIGS. 6 through 9 are cross-sectional views showing a method of manufacturing a POP according to a first embodiment of the present invention.

Referring to FIG. 6, the second package 250 of FIG. 4 is stacked on the first package 150 of FIGS. 1 and 2. The second circuit substrate 200 is stacked on the first circuit substrate 100. The first package 150 and the second package 250 are electrically connected by attaching the second circuit substrate 200 onto the internal connection members 102 on the first circuit substrate 100. That is, the first package 150 and the second package 250 are stacked on a circuit substrate level. The first package 150 and the second package 250 are electrically connected to each other by the electrical connection of the internal connection members 102 to the second circuit substrate 200.

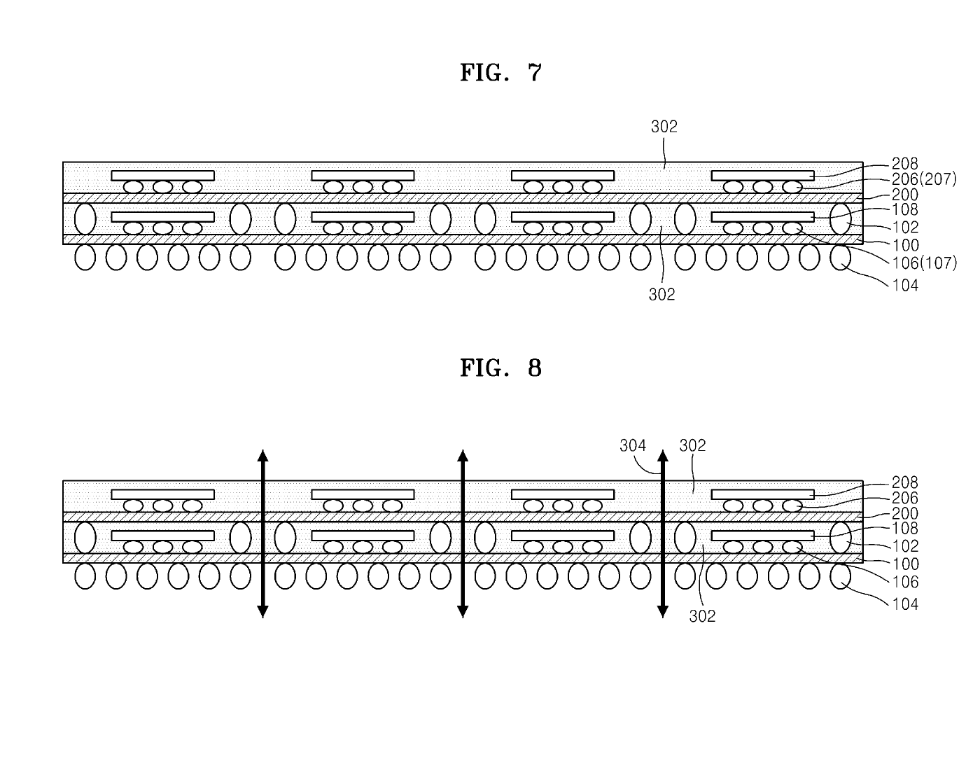

Referring to FIG. 7, an encapsulant 302 is formed to encapsulate or seal the first package 150 and the second package 250. That is, the encapsulant 302 is formed to encapsulate or seal the first circuit substrate 100, the internal connection members 102, the first chip connection members 106, the first chips 108, the second circuit substrate 200, the second chip connection members 206, and the second chips 208. The encapsulant 302 may be formed by using a molding process. The encapsulant 302 may be formed of, for example, an epoxy molding compound.

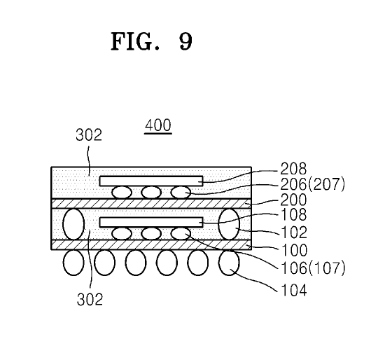

Referring to FIGS. 8 and 9, as shown in FIG. 8, the first circuit substrate 100, the second circuit substrate 200, and the encapsulant 302 are cut along cutting lines 304. The cutting lines 304 are defined to separate package-on-packages (POP) 400 of the first and second chips 108 and 208.

As a result, as depicted in FIG. 9, the POP 400, in which the first chip 108 and the second chip 208 are respectively formed on the first circuit substrate 100 and the second circuit substrate 200, is formed.

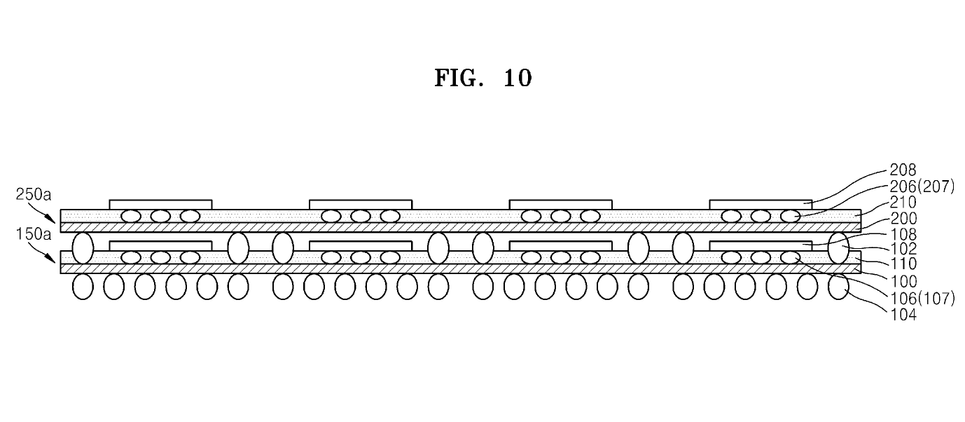

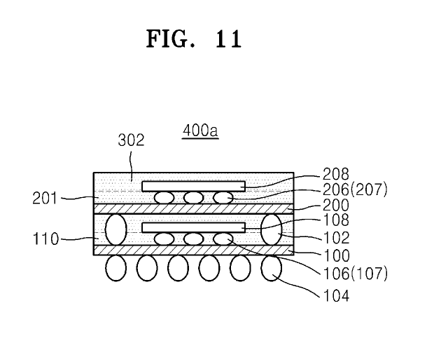

FIGS. 10 and 11 are cross-sectional views showing a method of manufacturing a POP 400a according to a second embodiment of the present invention.

Specifically, the POP 400a according to the second embodiment is the same as the POP 400 according to the first embodiment, except the first underfill layer 110 and the second underfill layer 210 are formed.

As depicted in FIG. 10, the POP 400a according to the second embodiment is formed by stacking the second package 250a of FIG. 5 on the first package 150a of FIG. 3. Next, as the method described with reference to FIG. 7, the encapsulant 302 is formed to encapsulate or seal the first package 150a and the second package 250a. Next, the POP 400a as depicted in FIG. 11 is formed by cutting the first circuit substrate 100, the second circuit substrate 200, and the encapsulant 302 as in the method described with reference to FIG. 8.

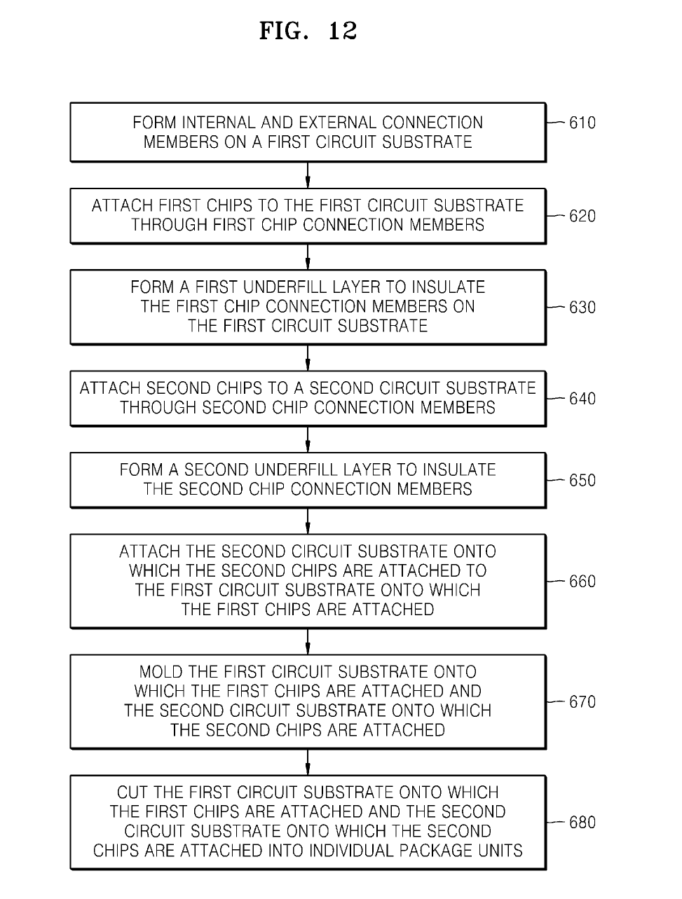

FIG. 12 is a flow chart for explaining a method of manufacturing a POP according to the first and second embodiments of the present invention.

Specifically, the internal connection members 102 and the external connection members 104 are formed on and under the first circuit substrate 100, respectively (Operation 610). The external connection members 104 may be formed separately from the process of forming the internal connection members 102. The external connection members 104 may be formed in a subsequent process without being formed in the current operation.

The first chips 108 that are connected to the first circuit substrate 100 through the first chip connection members 106 are attached onto the first circuit substrate 100 (operation 620). The first chips 108 are attached onto the first circuit substrate 100 between the internal connection members 102. The first underfill layer 110 that insulates the first chip connection members 106 is formed on the first circuit substrate 100 (operation 630). The first underfill layer 110 may not be formed, if unnecessary.

The second chips 208 that are connected to the second circuit substrate 200 through the second chip connection members 206 are attached onto the second circuit substrate 200 (operation 640). The second underfill layer 210 is formed on the second circuit substrate 200 to insulate the second chip connection members 206 (operation 650). The second underfill layer 210 may not be formed, if unnecessary.

The second circuit substrate 200 onto which the second chips 208 are attached is stacked on and attached to the first circuit substrate 100 onto which the first chips 108 are attached (operation 660). The first circuit substrate 100 and the second circuit substrate 200 are electrically connected by attaching the internal connection members 102 of the first circuit substrate 100 to the second circuit substrate 200.

That is, the first circuit substrate 100 and the second circuit substrate 200 are electrically connected by stacking the first circuit substrate 100 and the second circuit substrate 200 on a circuit substrate level. When the first circuit substrate 100 and the second circuit substrate 200 are stacked on the circuit substrate level, POPs may be stably obtained at a lower cost and with a simpler process than stacking packages that are manufactured by using an individual molding and cutting process on a chip level.

In other words, if packages are manufactured through an individual molding and cutting process, a high cost is required due to the individual molding and cutting process. Also, in order to stack the packages to which a molding is completed, a process of forming vias in an encapsulant may be necessary, thereby increasing costs due to a complicated process. However, in the current invention, a molding process, a cutting process, and a process of forming vias are unnecessary. Therefore, POPs may be stably obtained at low cost and with a simple process.

Next, the second circuit substrate 200 onto which the second chips 208 are attached is molded on the first circuit substrate 100 onto which the first chips 108 are attached (operation 670). The first circuit substrate 100 and the second circuit substrate 200 are encapsulated or sealed. The manufacture of the POPs 400 is completed by cutting the first circuit substrate 100 onto which the first chips 108 are attached and the second circuit substrate 200 onto which the second chips 208 are attached into individual package units (operation 680).

The POPs 400 in which the first chips 108 and the second chips 208 are respectively formed on the first circuit substrate 100 and the second circuit substrate 200 are formed by cutting the first circuit substrate 100, the second circuit substrate 200, and the encapsulant 302 into individual package units.

In the method of manufacturing POPs, according to the present invention, the manufacture of the first package is completed by attaching the first chips to the first circuit substrate on which the internal connection members are formed, and the manufacture of the second package is completed by attaching the second chips on the second circuit substrate. Next, in the method of manufacturing the POPs, according to the present invention, the first circuit substrate and the second circuit substrate are attached to each other, and the encapsulant is formed to encapsulate or seal the first and second circuit substrates. Afterwards, the POPs are formed by cutting the first and second circuit substrates and the encapsulant.

As described above, in the method of manufacturing POPs, according to the present invention, the first and second circuit substrates are stacked on a circuit substrate level, a molding process is performed, and afterwards, a cutting process is performed. Accordingly, the POPs having multifunction and high capacity may be stably obtained at a lower cost and with a simple process than stacking first and second packages that are manufactured by using an individual molding and cutting process on a chip level.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A method of manufacturing package-on-packages (POPs), the method comprising:
forming a plurality of internal connection members that are separated from each other in a direction parallel to a first circuit substrate on the first circuit substrate;
forming a first package by attaching a plurality of first chips between the internal connection members on the first circuit substrate;
forming a second package by attaching a plurality of second chips that are separated from each other in a direction parallel to a second circuit substrate on the second circuit substrate;
electrically connecting the first circuit substrate and the second circuit substrate by stacking and attaching the second circuit substrate onto internal connection members formed on the first circuit substrate on a circuit substrate level;
forming an encapsulant to encapsulate the first package and the second package; and
forming the POPs in which the first chips and the second chips are respectively formed on the first circuit substrate and the second circuit substrate by cutting the first circuit substrate, the second circuit substrate, and the encapsulant.

2. The method of claim 1, further comprising forming external connection members on a lower surface of the first circuit substrate.

3. The method of claim 1, wherein the first chips and the second chips are electrically connected to the first circuit substrate and the second circuit substrate respectively through first chip connection members and second chip connection members.

4. The method of claim 3, wherein the first and second chip connection members are formed as a plurality of chip connection terminals.

5. The method of claim 4, further comprising forming an underfill layer between the chip connection terminals of the first circuit substrate or the second circuit substrate.

6. The method of claim 1, wherein the first and second chips are respectively attached to the first and second circuit substrates in a flip chip method.

7. The method of claim 1, wherein the chip connection terminals and the internal connection members are formed as solder balls.

8. The method of claim 1, wherein the second chips are of the same kind as or a different kind than the first chips.

9. The method of claim 1, wherein the internal connection members have a height greater than that of the first chips on the first circuit substrate.

10. A method of manufacturing package-on-packages (POPs), the method comprising:
forming a plurality of internal connection members that are separated from each other on a first circuit substrate;
forming a first package by attaching a plurality of first chips between the internal connection members on the first circuit substrate;
forming a second package by attaching a plurality of second chips that are separated from each other on a second circuit substrate;
electrically connecting the first circuit substrate and the second circuit substrate by stacking the second circuit substrate onto the internal connection members;
forming an encapsulant to encapsulate the first package and the second package; and
forming the POPs in which the first chips and the second chips are respectively formed on the first circuit substrate and the second circuit substrate by cutting a portion of the first circuit substrate, the second circuit substrate, and the encapsulant.
